(19) United States
(12) Patent Application Publication
(10) Pub. No.: US 2026/0343954 A1
(43) Pub. Date: Oct. 29, 2026

(54) SEMICONDUCTOR DEVICE, METHOD OF MANUFACTURING THE SAME, AND APPARATUS INCLUDING THE SEMICONDUCTOR DEVICE

(71) Applicant: Samsung Electronics Co., Ltd., Suwon-si (KR)

(72) Inventors: Hajun SUNG, Suwon-si (KR); Kyooho JUNG, Suwon-si (KR); Kwanghee LEE, Suwon-si (KR); Daehyuk SON, Suwon-si (KR); Sangwook KIM, Suwon-si (KR)

(73) Assignee: Samsung Electronics Co., Ltd., Suwon-si (KR)

(21) Appl. No.: 19/572,087

(22) Filed: Mar. 19, 2026

(30) Foreign Application Priority Data
Apr. 28, 2025 (KR) 10-2025-0055178
Aug. 13, 2025 (KR) 10-2025-0112052

(51) Int. Cl. H10D 30/67; H10B 51/10; H10B 51/20; H10B 51/30; H10D 30/01; H10D 30/69

(52) U.S. Cl. CPC H10D 30/6756; H10B 51/10; H10B 51/20; H10B 51/30; H10D 30/0314; H10D 30/0318; H10D 30/0415; H10D 30/6731; H10D 30/6735; H10D 30/6736; H10D 30/6757; H10D 30/701

(57) ABSTRACT

Provided are a semiconductor device, a method of manufacturing the semiconductor device, and an apparatus including the semiconductor device. The semiconductor device may include an amorphous oxide semiconductor layer including indium (In) and a first metal element different from indium (In), a gate electrode apart from the amorphous oxide semiconductor layer, a gate insulating layer between the amorphous oxide semiconductor layer and the gate electrode, and a first electrode and a second electrode provided apart from each other and in contact with the amorphous oxide semiconductor layer. An oxygen diffusivity of the amorphous oxide semiconductor layer may be less than oxygen diffusivity of indium oxide (In₂O₃).

### CROSS-REFERENCE TO RELATED APPLICATION

This application is based on and claims priority under 35 U.S.C. § 119 to

Korean Patent Application No. 10-2025-0055178, filed on Apr. 28, 2025, in the Korean Intellectual Property Office, and Korean Patent Application No. 10-2025-0112052, filed on Aug. 13, 2025, in the Korean Intellectual Property Office, the disclosures of which are incorporated by reference herein in their entireties.

### BACKGROUND

### 1. Field

The disclosure relates to a semiconductor device, a method of manufacturing the semiconductor device, and an apparatus including the semiconductor device, and more particularly, to a semiconductor device including an oxide semiconductor layer, a method of manufacturing the semiconductor device, and/or an apparatus including the semiconductor device.

### 2. Description of the Related Art

Transistors, which are semiconductor devices having an electrical switching function, may be used in various integrated circuit (IC) devices including memories, driving ICs, and logic devices. The area occupied by transistors in IC devices has been rapidly reduced to increase the integration density of IC devices, and therefore, research has been conducted to maintain the transistor performance while reducing the size thereof.

Research has been conducted for many years into oxide semiconductor devices that are transparent and characterized by a wide bandgap of 3.0 eV or greater. Oxide semiconductor devices used as driving devices for large-area displays are remarkable for their low off-current and high on/off ratio. Integration density may be increased by applying oxide semiconductor devices having these characteristics to memory or logic devices or by stacking oxide semiconductor devices on Si-based devices.

However, oxide semiconductor devices may suffer from performance degradation due to short-channel effects caused by scaling down.

### SUMMARY

Provided are a semiconductor device having improved heat resistance and an apparatus including the semiconductor device.

Provided are a semiconductor device having improved operational speed and an apparatus including the semiconductor device.

Additional aspects will be set forth in part in the description which follows and, in part, will be apparent from the description, or may be learned by practice of the presented embodiments of the disclosure.

According to an aspect of the disclosure, a semiconductor device may include an amorphous oxide semiconductor layer including indium (In) and a first metal element, the first metal element being different from indium (In), a gate electrode apart from the amorphous oxide semiconductor layer, a gate insulating layer between the amorphous oxide semiconductor layer and the gate electrode, and a first electrode and a second electrode apart from each other and in contact with the amorphous oxide semiconductor layer. An oxygen diffusivity of the amorphous oxide semiconductor layer may be less than an oxygen diffusivity of indium oxide (In₂O₃).

In some embodiments, an amount of Indium (In) may be 70 at % or more of a total metal content in the amorphous oxide semiconductor layer.

In some embodiments, an amount of the first metal element may be more than 1 at % of a total metal content in the amorphous oxide semiconductor layer.

In some embodiments, an amount of the first metal element may be less than 30 at % of a total metal content in the amorphous oxide semiconductor layer.

In some embodiments, an amount of the first metal element may be 10 at % to 20 at % of a total metal content in the amorphous oxide semiconductor layer.

In some embodiments, the first metal element may include at least one selected from aluminum (Al), silicon (Si), gallium (Ga), yttrium (Y), and hafnium (Hf).

In some embodiments, the amorphous oxide semiconductor layer may have a thickness of 10 nm or less.

In some embodiments, the amorphous oxide semiconductor layer may include a crystalline phase in an amount of greater than 0 % and less than or equal to 5 %.

In some embodiments, the amorphous oxide semiconductor layer may be a first oxide semiconductor layer, and the semiconductor device further may include a second oxide semiconductor layer. The second oxide semiconductor layer may be in contact with the first oxide semiconductor layer and the second oxide semiconductor layer may be apart from the first electrode and the second electrode.

In some embodiments, the second oxide semiconductor layer may be in contact with the gate insulating layer.

In some embodiments, an oxygen diffusivity of the second oxide semiconductor layer may be greater than an oxygen diffusivity of the first oxide semiconductor layer.

In some embodiments, the second oxide semiconductor layer may include indium (In) in an amount of 70 at % or more based on a total metal content thereof, and the second oxide semiconductor layer may further include a second metal element. The second metal element may be different from indium (In) and the first metal element.

In some embodiments, the second metal element may include at least one selected from zinc (Zn), tin (Sn), germanium (Ge), and tungsten (W).

In some embodiments, a bottom portion of the amorphous oxide semiconductor layer may be in contact with the first electrode, a first vertical extension portion of the amorphous oxide semiconductor layer may extend from an end of the bottom portion in a direction perpendicular to the first electrode, and a second vertical extension portion of the amorphous oxide semiconductor layer may extend from another end of the bottom portion in the direction perpendicular to the first electrode.

In some embodiments, the amorphous oxide semiconductor layer may have a cylindrical shell shape, the gate insulating layer may be on an inner surface of the amorphous oxide semiconductor layer, the gate electrode may be on an inner surface of the gate insulating layer, and the first electrode and the second electrode may be on an outer surface of the amorphous oxide semiconductor layer.

In some embodiments, at least one of the first electrode and the second electrode may surround ⅕ or more of the outer surface of the amorphous oxide semiconductor layer.

In some embodiments, the gate insulating layer may include a ferroelectric material.

According to another aspect of the disclosure, an electronic apparatus may include a memory device, and a memory controller configured to control the memory device to at least one of read data from the memory device or write data to the memory device. The memory device may include a semiconductor device. The semiconductor device may include an amorphous oxide semiconductor layer, a gate electrode apart from the amorphous oxide semiconductor layer, a gate insulating layer between the amorphous oxide semiconductor layer and the gate electrode, a first electrode, and a second electrode. The amorphous oxide semiconductor layer may include indium (In) and a first metal element. The first metal element may be different from indium (In). The first electrode and the second electrode may be apart from each other and in contact with the amorphous oxide semiconductor layer. An oxygen diffusivity of the amorphous oxide semiconductor layer may be less than an oxygen diffusivity of indium oxide (In₂O₃).

According to another aspect of the disclosure, a method of manufacturing a semiconductor device includes may include forming an amorphous oxide semiconductor layer on a substrate at a process temperature of 300 °C or less; forming a gate insulating layer on the amorphous oxide semiconductor layer; and forming a gate electrode on the gate insulating layer. The amorphous oxide semiconductor layer may include indium (In) and a first metal element. The first metal element may be different from indium (In), and an oxygen diffusivity of the amorphous oxide semiconductor layer may be less than an oxygen diffusivity of indium oxide (In₂O₃).

In some embodiments, the first metal element may include at least one selected from aluminum (Al), silicon (Si), gallium (Ga), yttrium (Y), and hafnium (Hf).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating a semiconductor device according to an embodiment;

FIG. 2 is a reference view illustrating a method of manufacturing a semiconductor device according to an embodiment;

FIG. 3 is a graph illustrating results of measuring the mean square displacement (MSD) of oxygen in indium oxide doped with different dopants according to examples;

FIG. 4 is a table illustrating results of measuring the diffusivity of oxygen in indium oxide doped with different dopants, according to an embodiment;

FIG. 5 is a table illustrating results of measuring the on-current and subthreshold swing of an oxide semiconductor layer according to the content of aluminum (Al) in an embodiment;

FIG. 6 is a view illustrating a semiconductor device according to another embodiment;

FIG. 7 is a view illustrating a semiconductor device according to another embodiment;

FIG. 8 is a view illustrating a semiconductor device according to another embodiment;

FIG. 9 is a view illustrating a semiconductor device including a plurality of oxide semiconductor layers, according to an embodiment;

FIG. 10 is a view illustrating a semiconductor device including a plurality of oxide semiconductor layers, according to another embodiment;

FIG. 11 is a view illustrating a semiconductor device according to another embodiment;

FIG. 12 is a view illustrating a semiconductor device according to another embodiment;

FIG. 13 is a perspective view schematically illustrating a structure of a memory device that is a type of semiconductor device, according to an embodiment.

FIG. 14 is a plan view illustrating the memory device shown in FIG. 13;

FIG. 15 is a cross-sectional view taken along line I-I′ of FIG. 14 schematically illustrating a cross-sectional structure according to an embodiment;

FIG. 16 is a block diagram illustrating an electronic system according to an embodiment;

FIG. 17 is a block diagram illustrating an electronic system according to an embodiment; and

FIG. 18 is a conceptual diagram schematically illustrating a device architecture applicable to an electronic apparatus according to an embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, semiconductor devices, methods of manufacturing the semiconductor devices, and apparatuses including the semiconductor devices will be described according to various embodiments with reference to the accompanying drawings. In the drawings, like reference numerals refer to like elements, and the sizes of elements may be exaggerated for clarity of illustration.

The terms of a singular form may include plural forms unless otherwise mentioned. It will be further understood that the terms “comprises” and/or “comprising” used herein specify the presence of stated features or elements, but do not preclude the presence or addition of one or more other features or elements. In the drawings, the sizes or thicknesses of elements may be exaggerated for clarity of illustration. In addition, when a material layer is referred to as being “above” or “on” a substrate or another layer, it may be directly on the substrate or the other layer while making contact with the substrate or the other layer or may be above the substrate or the other layer with a third layer therebetween. In the following descriptions of the embodiments, a material of each layer is merely an example, and another material may be used.

In the disclosure, terms such as “unit” or “module” may be used to denote a unit that has at least one function or operation and is implemented with hardware, software, or a combination of hardware and software.

Specific executions described herein are merely examples and do not limit the scope of the disclosure in any way. For simplicity of description, other functional aspects of conventional electronic configurations, control systems, software and the systems may be omitted.

Furthermore, line connections or connection members between elements depicted in the drawings represent functional connections and/or physical or circuit connections by way of example, and in actual applications, they may be replaced or embodied as various additional functional connections, physical connections, or circuit connections.

An element referred to with the definite article or a demonstrative determiner may be construed as the element or the elements even though it has a singular form.

Operations of a method may be performed in an appropriate order unless explicitly described in terms of order or described to the contrary. In addition, examples or terms (for example, “such as” and “etc.”) are used for the purpose of description and are not intended to limit the scope of the disclosure unless defined by the claims.

Expressions such as “at least one” preceding a list of elements specify the entire list of elements and do not specify individual elements within the list. For example, expressions such as “at least one of A, B, and C” or “at least one selected from the group consisting of A, B, and C” may be interpreted as indicating only A, only B, only C, or any combination of two or more of A, B, and C such as ABC, AB, BC, and AC.

When terms such as “approximately” or “substantially” are used in relation to a numerical value, the numerical value may be interpreted as including manufacturing or operational variations from the numerical value (for example, a variation of ±10 %). Furthermore, when terms such as “generally” and “substantially” are used in relation to geometric shapes, geometric precision may not be required, and permissible variations of the geometric shapes may be within the scope of embodiments. In addition, regardless of whether numerical values or shapes are qualified or described by “approximately” or “substantially,” the numerical values or shapes may be interpreted as including manufacturing or operational variations from the numerical values or shapes (for example, a variation of ±10 %).

It will be understood that although terms such as “first” and “second” are used herein to describe various elements, these elements should not be limited by these terms. These terms are only used to distinguish one element from other elements.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Examples or terms are just used herein to describe technical ideas and should not be considered for purposes of limitation unless defined by the claims.

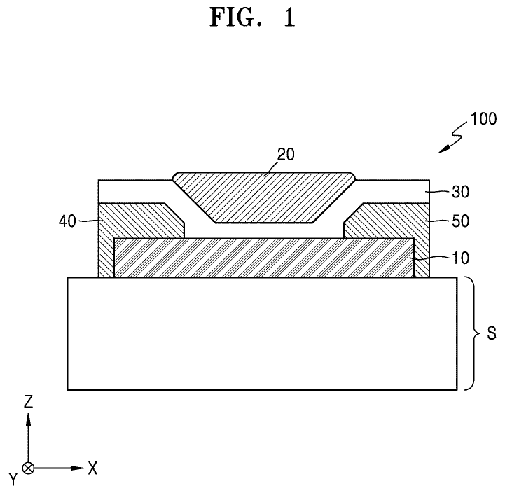

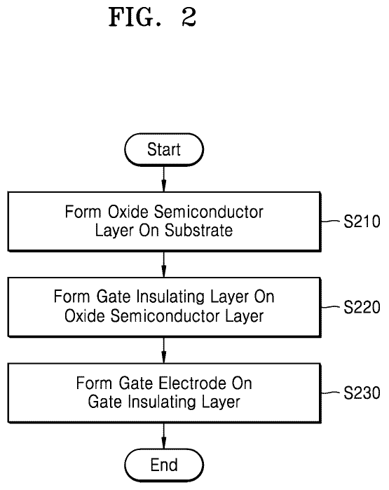

FIG. 1 is a view illustrating a semiconductor device 100 according to an embodiment, and FIG. 2 is a reference view illustrating a method of manufacturing the semiconductor device 100 according to an embodiment. In an embodiment, the semiconductor device 100 may be a component of a transistor or a memory cell. The transistor may be a component different from the memory cell or may be a component of the memory cell.

Referring to FIG. 1, the semiconductor device 100 may include a substrate S, an oxide semiconductor layer 10 disposed on the substrate S, a gate electrode 20 disposed apart from the oxide semiconductor layer 10, and a gate insulating layer 30 disposed between the oxide semiconductor layer 10 and the gate electrode 20. The semiconductor device 100 may further include a first electrode 40 and a second electrode 50 that are arranged apart from each other and in contact with the oxide semiconductor layer 10. One of the first electrode 40 and the second electrode 50 may be a source electrode and the other may be a drain electrode. The first electrode 40 and the second electrode 50 may be arranged apart from each other on the same surface (for example, an upper surface) of the oxide semiconductor layer 10. The semiconductor device 100 may be referred to as a transistor having a planar structure.

Referring to FIG. 2, the oxide semiconductor layer 10 may be formed on the substrate S (S210), the gate insulating layer 30 may be formed on the oxide semiconductor layer 10 (S220), and the gate electrode 20 may be formed on the gate insulating layer 30 (S230). In the semiconductor device 100 shown in FIG. 1, the first electrode 40 and the second electrode 50 may be formed on the oxide semiconductor layer 10 after forming the oxide semiconductor layer 10 and before forming the gate insulating layer 30. However, embodiments are not limited thereto. At least one selected from the first electrode 40 and the second electrode 50 may be formed before forming the oxide semiconductor layer 10. For example, the first electrode 40 and the second electrode 50 may be formed apart from each other on the substrate S, and then, the oxide semiconductor layer 10 may be formed in contact with the first electrode 40 and the second electrode 50.

The oxide semiconductor layer 10, the gate electrode 20, the gate insulating layer 30, the first electrode 40, and the second electrode 50 may be formed through general semiconductor processes such as atomic layer deposition (ALD), plasma-enhanced ALD (PE-ALD), sputtering, or wet processing.

The substrate S may be an insulating substrate, or a semiconductor substrate having an insulating layer formed on a surface thereof. Alternatively, the substrate S may be a semiconductor substrate. The semiconductor substrate may include, for example, Si, Ge, SiGe, or a Group III-V semiconductor material. For example, the substrate S may be a silicon substrate having a silicon oxide layer formed on a surface thereof, but is not limited thereto.

In one embodiment, the oxide semiconductor layer 10 may include two or more types of metal elements. Among the metal elements included in the oxide semiconductor layer 10, indium (In) may have the highest content. For example, the content of indium (In) may be 60 at % or more, or 70 at % or more.

Because indium (In) has a low bond dissociation energy with oxygen, indium (In) may easily form oxygen vacancies and thus may increase the concentration of carriers in the oxide semiconductor layer 10. In addition, indium (In) may readily form an electron conduction path through the 5 s orbital thereof. However, when the oxide semiconductor layer 10 includes only indium oxide (In₂O₃), the oxide semiconductor layer 10 may always be in a turned-on state because of an excessively high carrier concentration, losing semiconductor characteristics. In addition, indium (In) is thermally unstable, and thus, when the oxide semiconductor layer 10 mainly includes indium (In), electrical characteristics of the oxide semiconductor layer 10 may change depending on a process temperature. For example, when the oxide semiconductor layer 10 is heated to about 400 °C or higher, oxygen may diffuse or disperse within the oxide semiconductor layer 10, and thus, electrical characteristics of the oxide semiconductor layer 10 may change.

In an embodiment, the oxide semiconductor layer 10 may include indium (In) and a first metal element different from indium (In). Because the oxide semiconductor layer 10 includes the first metal element, the oxygen diffusivity of the oxide semiconductor layer 10 may be less than that of indium oxide (In₂O₃). The first metal element may include at least one selected from aluminum (Al), silicon (Si), gallium (Ga), yttrium (Y), and hafnium (Hf). In an embodiment, indium oxide (In₂O₃) may be formed under the same conditions as the oxide semiconductor layer 10. For example, the indium oxide (In₂O₃) may be amorphous.

The content of the first metal element may be greater than 1 at %, greater than or equal to 5 at %, or greater than or equal to 10 at %, and may be less than or equal to 20 at %, or less than 30 at %. For example, the content of the first metal element may be from about 10 at % to about 20 at %. Here, the content of the first metal element may refer to the ratio of the first metal element to to total metal elements included in the oxide semiconductor layer 10. When the content of the first metal element is excessively low, that is, 1 at % or less, the effect of the first metal element in decreasing the diffusion of oxygen in the oxide semiconductor layer 10 may be insignificant. When the content of the first metal element is excessively high, that is, 30 at % or more, the concentration of carriers in the oxide semiconductor layer 10 may decrease, deteriorating semiconductor characteristics of the oxide semiconductor layer 10.

The length of the oxide semiconductor layer 10 may be about 1 μm or less, about 500 nm or less, about 100 nm or less, about 50 nm or less, or about 30 nm or less. The thickness of the oxide semiconductor layer 10 may be about 20 nm or less, about 10 nm or less, about 8 nm or less, or about 7 nm or less. When the semiconductor device 100 is a component of a transistor or a memory cell, the oxide semiconductor layer 10 may serve as a channel layer. Here, the length of the oxide semiconductor layer 10 may refer to a distance between the first electrode 40 and the second electrode 50 that are in contact with the oxide semiconductor layer 10, and the thickness of the oxide semiconductor layer 10 may refer to a dimension of the oxide semiconductor layer 10 in a direction (Z direction) perpendicular to the length direction of the oxide semiconductor layer 10. For example, the thickness of the oxide semiconductor layer 10 may be defined in a direction (Z-axis direction) perpendicular to a surface of the substrate S.

In an embodiment, the oxide semiconductor layer 10 may be amorphous. In an embodiment, the oxide semiconductor layer 10 may be amorphous because the oxide semiconductor layer 10 is formed at a low process temperature, for example, at a process temperature of about 300 °C or lower. Because the oxide semiconductor layer 10 includes the first metal element, the amorphous phase of the oxide semiconductor layer 10 may be maintained even during a post-thermal treatment process for the semiconductor device 100. In an embodiment, because the amorphous phase of the oxide semiconductor layer 10 is maintained, electrical characteristics of the oxide semiconductor layer 10 may not change even after heat treatment. In an embodiment, the expression “the oxide semiconductor layer 10 is amorphous” may indicate that the oxide semiconductor layer 10 has no crystalline phase or a crystal phase in an amount of 5 % or less.

The gate electrode 20 may include at least one selected from a metal, a metal nitride, a metal carbide, and polysilicon. For example, the metal may include aluminum (Al), tungsten (W), molybdenum (Mo), titanium (Ti), or tantalum (Ta). For example, the metal nitride may include titanium nitride (TiN) or tantalum nitride (TaN). For example, the metal carbide may be a metal carbide doped with (or containing) aluminum or silicon, such as TiAlC, TaAlC, TiSiC, or TaSiC.

The gate electrode 20 may have a multilayer structure in which a plurality of materials are stacked. For example, the gate electrode 20 may have a stacked structure of a metal nitride layer/metal element layer such as TiN/Al, or a stacked structure of a metal nitride layer/metal carbide layer/metal element layer such as TiN/TiAlC/W. The gate electrode 20 may include titanium nitride (TiN) or molybdenum (Mo), and the examples described above may be variously modified. When the semiconductor device 100 is a component of a memory cell, the gate electrode 20 may be a region of a word line.

In an embodiment, the semiconductor device 100 may further include the gate insulating layer 30 between the oxide semiconductor layer 10 and the gate electrode 20. The gate insulating layer 30 may include a paraelectric material. The gate insulating layer 30 may include an oxide containing at least one selected from hafnium (Hf), zirconium (Zr), aluminum (Al), and silicon (Si).

The first electrode 40 and the second electrode 50 may each include a metallic material. The first electrode 40 and the second electrode 50 may each include at least one selected from tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), antimony (Sb), vanadium (V), ruthenium (Ru), platinum (Pt), zinc (Zn), and magnesium (Mg). Alternatively, the first electrode 40 and the second electrode 50 may each be a nitride containing any of the listed materials. For example, the first electrode 40 and the second electrode 50 may each include at least one selected from W, TiN, Mo, MoN, Ru, and TiSiN.

During a heat treatment process, indium (In) or oxygen (O) included in the oxide semiconductor layer 10 may easily migrate into a metallic material (for example, the first electrode 40 or the second electrode 50) that is in contact with the oxide semiconductor layer 10. Therefore, the oxide semiconductor layer 10 may further include a material that limits and/or prevents indium (In) or oxygen (O) from easily migrating into the first electrode 40 or the second electrode 50.

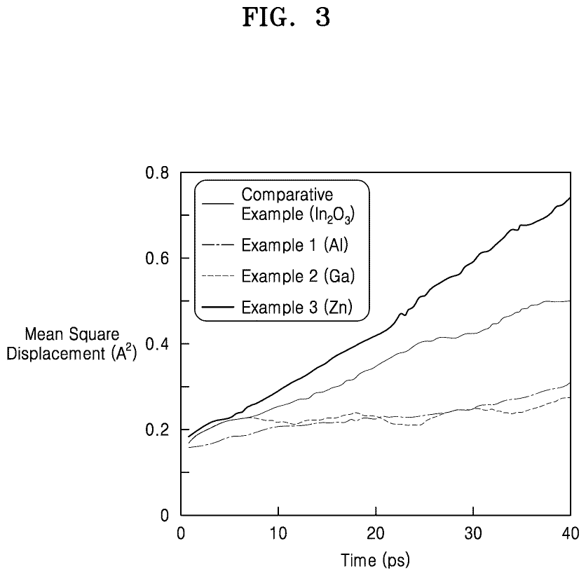

FIG. 3 is a graph illustrating results of measuring the mean square displacement (MSD) of oxygen in indium oxide doped with different dopants according to examples. In a comparative example, the MSD of oxygen over time was measured in an oxide semiconductor layer including only indium oxide (In₂O₃). In Example 1, the MSD of oxygen over time was measured in an oxide semiconductor layer including indium oxide (In₂O₃) doped with 10 at % of aluminum (Al). In Example 2, the MSD of oxygen over time was measured in an oxide semiconductor layer including indium oxide (In₂O₃) doped with 10 at % gallium (Ga). In Example 3, the MSD of oxygen over time was measured in an oxide semiconductor layer including indium oxide (In₂O₃) doped with 10 at % zinc (Zn).

It may be confirmed that the MSD of oxygen in the oxide semiconductor layers doped with aluminum (Al) and gallium (Ga) is less than that in the oxide semiconductor layer including only indium oxide (In₂O₃). In contrast, it may be confirmed that the MSD of oxygen in the oxide semiconductor layer doped with zinc (Zn) is greater than that in the oxide semiconductor layer including only indium oxide (In₂O₃).

When indium oxide (In₂O₃) is doped with zinc (Zn), the MSD of oxygen significantly increases, which is expected to reduce heat resistance stability. In addition, when an oxide semiconductor layer including indium oxide (In₂O₃) is doped with gallium (Ga) or aluminum (Al), the MSD of oxygen decreases, and therefore, changes in the characteristics of the oxide semiconductor layer after heat treatment may be limited and/or suppressed, leading to high heat resistance stability.

Because the MSD of oxygen is convertible into oxygen diffusivity, it may be inferred that the diffusivity of oxygen varies depending on the type of dopant with which indium oxide is doped.

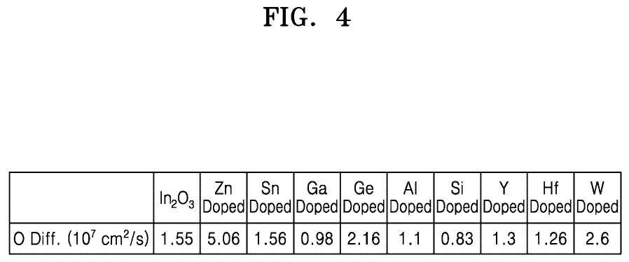

FIG. 4 is a table illustrating results of measuring the diffusivity of oxygen in indium oxide doped with different dopants, according to an embodiment. FIG. 4 shows the oxygen diffusivity of amorphous oxide semiconductor layers each containing a metal element in an amount of 10 at % and indium in an amount of 90 at % and formed at a low process temperature (for example, 300 °C or lower).

Referring to FIG. 4, it may be confirmed that the oxygen diffusivity of oxide semiconductor layers including gallium (Ga), aluminum (Al), silicon (Si), yttrium (Y), and hafnium (Hf) is less than that of an oxide semiconductor layer including only indium oxide (In₂O₃). In contrast, it may be confirmed that the oxygen diffusivity of oxide semiconductor layers including zinc (Zn), tin (Sn), germanium (Ge), and tungsten (W) is greater than that of the oxide semiconductor layer including only indium oxide (In₂O₃).

Oxide semiconductor layers having low oxygen diffusivity exhibit heat resistance stability. Therefore, in an embodiment, the first metal element described above may include at least one selected from gallium (Ga), aluminum (Al), silicon (Si), yttrium (Y), and hafnium (Hf).

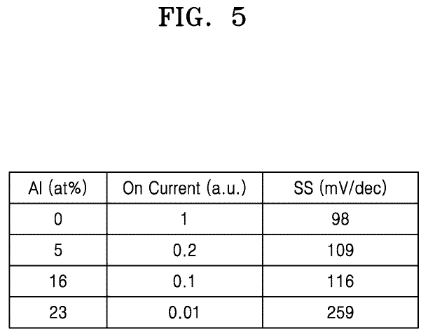

FIG. 5 is a table illustrating results of measuring the on-current and subthreshold swing of oxide semiconductor layers with respect to the content of aluminum (Al) according to embodiments; It may be confirmed that when indium oxide (In₂O₃) is doped with aluminum (Al), on-current decreases, and subthreshold swing increases. The subthreshold swing of an oxide semiconductor layer with an aluminum (Al) content of about 15 at % or less is slightly above 100 mV/dec. Thus, the oxide semiconductor layer is expected to be applicable to a memory device according to an embodiment.

In addition, the subthreshold swing of an oxide semiconductor layer with an aluminum (Al) content of about 23 at % is greater than 200 mV/dec. Thus, it may be difficult to apply the oxide semiconductor layer to a memory device according to an embodiment.

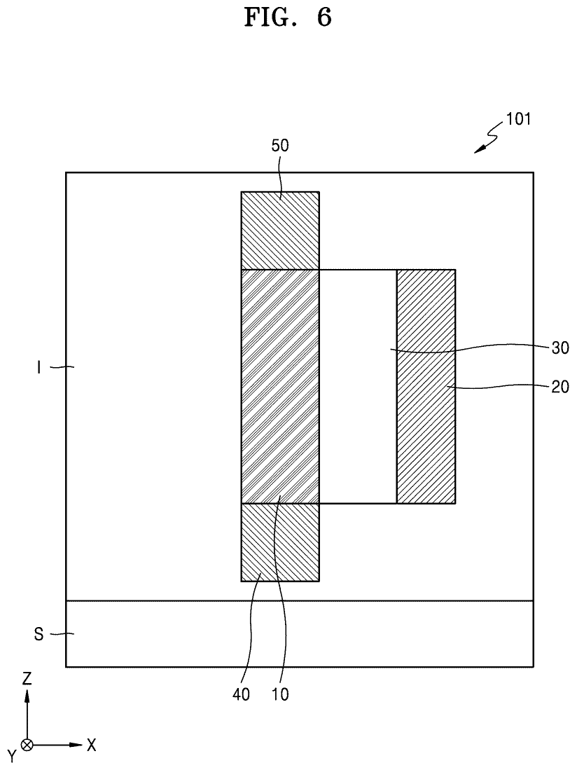

FIG. 6 is a view illustrating a semiconductor device 101 according to another embodiment. In FIGS. 1 and 6, elements denoted with the same reference numerals have substantially the same structures and effects, and therefore, repeated descriptions thereof are omitted.

Referring to FIG. 6, the semiconductor device 101 may include a substrate S, a first electrode 40 disposed above the substrate S, an oxide semiconductor layer 10 disposed on the first electrode 40, and a second electrode 50 disposed on the oxide semiconductor layer 10. The materials of the oxide semiconductor layer 10, a gate electrode 20, a gate insulating layer 30, the first electrode 40, and the second electrode 50 are as described above, and therefore, repeated descriptions thereof are omitted.

The oxide semiconductor layer 10 may be disposed such that the length direction (Z-axis direction) of the oxide semiconductor layer 10 may be perpendicular to the substrate S. In the present specification, the length direction of an element refers to the direction in which the element has the longest dimension when viewed in a drawing.

The first electrode 40 and the second electrode 50 may be arranged apart from each other in a direction (Z-axis direction) perpendicular to the substrate S. For example, the first electrode 40, the oxide semiconductor layer 10, and the second electrode 50 may be arranged in a line in the direction perpendicular to the substrate S or in the thickness direction (Z-axis direction) of the first electrode 40.

The gate electrode 20 may be disposed on one side of the oxide semiconductor layer 10. The gate electrode 20 may serve as a current-control electrode. The gate insulating layer 30 may be disposed between the oxide semiconductor layer 10 and the gate electrode 20. The gate electrode 20 may be disposed such that the length direction (Z-axis direction) of the gate electrode 20 may be perpendicular to the substrate S. The oxide semiconductor layer 10, the gate insulating layer 30, and the gate electrode 20 may be arranged in a line in a horizontal direction (X-axis direction) parallel to the substrate S.

An insulating layer I may be disposed on the substrate S to fill an empty space. The first electrode 40 may be disposed apart from the substrate S by the insulating layer I.

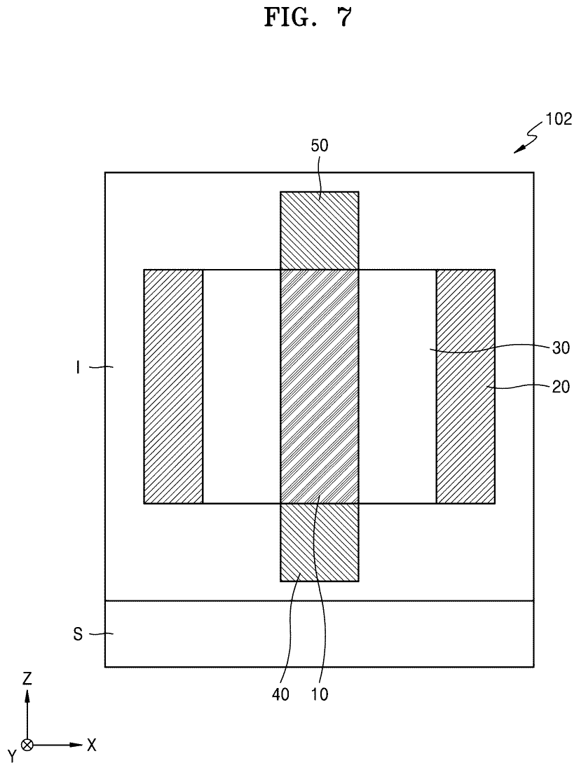

FIG. 7 is a view illustrating a semiconductor device 102 according to another embodiment. In FIGS. 6 and 7, elements denoted with the same reference numerals have substantially the same structures and effects, and therefore, repeated descriptions thereof are omitted.

Referring to FIG. 7, the semiconductor device 102 may include a first electrode 40, an oxide semiconductor layer 10, and a second electrode 50, which are arranged in a direction (Z-axis direction) perpendicular to a substrate S. A gate insulating layer 30 may be disposed around the oxide semiconductor layer 10, and a gate electrode 20 may be disposed around the oxide semiconductor layer 10. Because the gate electrode 20 is disposed around the oxide semiconductor layer 10, the mutually-facing area between the gate electrode 20 and the oxide semiconductor layer 10 may be increased, thereby mitigating short-channel effects.

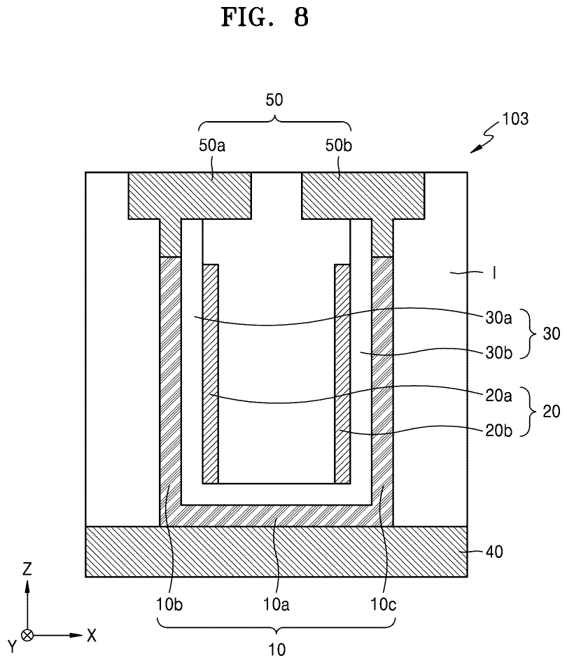

FIG. 8 is a view illustrating a semiconductor device 103 according to another embodiment. In FIG. 8, elements denoted by the same reference numerals as those described above have substantially the same structures and effects as previously described, and therefore, repeated descriptions thereof are omitted.

Referring to FIG. 8, the semiconductor device 103 may include a first electrode 40 and an oxide semiconductor layer 10 disposed on the first electrode 40.

From the perspective of a cross-sectional view perpendicular to a surface of the first electrode 40, the oxide semiconductor layer 10 may include a first region extending in a direction parallel to the surface of the first electrode 40, and a second region extending from the first electrode 40 toward a second electrode 50. For example, the oxide semiconductor layer 10 may have a U-shaped cross-sectional structure. The oxide semiconductor layer 10 may include a bottom portion 10a extending parallel to the surface of the first electrode 40, a first vertical extension portion 10b extending from an end of the bottom portion 10a in a direction (Z-axis direction) perpendicular to the surface of the first electrode 40, and a second vertical extension portion 10c extending from the other end of the bottom portion 10a in the direction (Z-axis direction) perpendicular to the surface of the substrate S. A lower surface of the bottom portion 10a may be referred to as a lower surface of the oxide semiconductor layer 10, and outer surfaces of the first vertical extension portion 10b and the second vertical extension portion 10c may be referred to as outer surfaces of the oxide semiconductor layer 10. The width of the bottom portion 10a may be defined as the width of the oxide semiconductor layer 10.

The second electrode 50 may be disposed on an upper portion of the oxide semiconductor layer 10. The second electrode 50 may function as a landing pad. The second electrode 50 may include a first sub-electrode 50a and a second sub-electrode 50b. The first sub-electrode 50a may be electrically connected to the first vertical extension portion 10b. The second sub-electrode 50b may be electrically connected to the second vertical extension portion 10c. The first sub-electrode 50a and the second sub-electrode 50b may not be electrically connected to each other.

In an embodiment, an upper portion of each of the first sub-electrode 50a and the second sub-electrode 50b may have a first width in a first horizontal direction (X-axis direction), and a lower portion of each of the first sub-electrode 50a and the second sub-electrode 50b may have a second width defined in the first horizontal direction and smaller than the first width. Each of the first sub-electrode 50a and the second sub-electrode 50b may have a T-shaped vertical cross-section.

A bottom surface of the lower portion of the first sub-electrode 50a may be disposed on an upper surface of the first vertical extension portion 10b, and a bottom surface of the lower portion of the second sub-electrode 50b may be disposed on an upper surface of the second vertical extension portion 10c. A bottom surface of a lower portion of the second electrode 50 may be positioned at a level higher than upper surfaces of a first gate electrode 20a and/or a second gate electrode 20b, and lateral wall portion of a lower portion of the second electrode 50 may be covered by a first gate insulating layer 30a and/or a second gate insulating layer 30b.

A gate electrode 20 may include the first gate electrode 20a disposed apart from the first vertical extension portion 10b, and a second gate electrode 20b disposed apart from the second vertical extension portion 10c. A gate insulating layer 30 may include the first gate insulating layer 30a disposed between the first vertical extension portion 10b and the first gate electrode 20a, and the second gate insulating layer 30b disposed between the second vertical extension portion 10c and the second gate electrode 20b.

The first gate electrode 20a and/or the second gate electrode 20b may extend in a second horizontal direction (Y-axis direction). The first gate electrode 20a and the second gate electrode 20b may be disposed apart from each other.

The semiconductor device 103 may have a vertical channel transistor (VCT) structure including a vertical channel region extending in a direction (Z direction) perpendicular to the surface of the first electrode 40.

The same electrical signal may be applied to the first gate electrode 20a and the second gate electrode 20b, and the same electrical signal may be applied to the first sub-electrode 50a and the second sub-electrode 50b. In this case, the semiconductor device 103 may operate as a single transistor.

Alternatively, independent electrical signals may be applied to the first gate electrode 20a and the second gate electrode 20b, respectively, and independent electrical signals may be applied to the first sub-electrode 50a and the second sub-electrode 50b, respectively. In this case, the semiconductor device 103 may operate as two transistors. For example, the oxide semiconductor layer 10, the first gate electrode 20a, the first gate insulating layer 30a, the first electrode 40, the first sub-electrode 50a may operate as one transistor, and the oxide semiconductor layer 10, the second gate electrode 20b, the second gate insulating layer 30b, the first electrode 40, and the second sub-electrode 50b may operate as another transistor.

In an embodiment, a semiconductor device may include a plurality of oxide semiconductor layers.

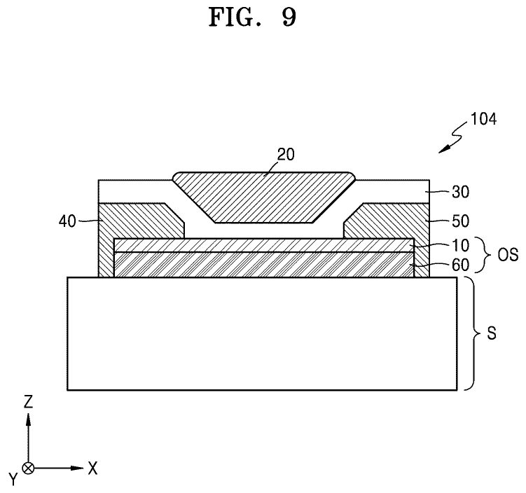

FIG. 9 is a view illustrating a semiconductor device 104 including a plurality of oxide semiconductor layers according to an embodiment. When comparing FIG. 1 and FIG. 9, an oxide semiconductor layer OS included in the semiconductor device 104 shown in FIG. 9 may include a first oxide semiconductor layer 10 having an oxygen diffusivity less than that of indium oxide, and a second oxide semiconductor layer 60 having an oxygen diffusivity greater than that of indium oxide.

The first oxide semiconductor layer 10 may be in contact with a first electrode 40 and a second electrode 50, and the second oxide semiconductor layer 60 may be in contact with the first oxide semiconductor layer 10 while being apart from the first electrode 40 and the second electrode 50 with the first oxide semiconductor layer 10 therebetween.

The first oxide semiconductor layer 10 corresponds to the oxide semiconductor layer 10 described with reference to FIG. 1, and therefore, a repeated description thereof is omitted.

The second oxide semiconductor layer 60 may have an oxygen diffusivity greater than that of indium oxide. The second oxide semiconductor layer 60 may include two or more types of metal elements. The content of indium may be the greatest among the metal elements included in the second oxide semiconductor layer 60. For example, the content of indium may be 60 at % or more, or 70 at % or more. The second oxide semiconductor layer 60 may include indium and a second metal element that is different from indium and the first metal element described above. Because the second oxide semiconductor layer 60 includes the second metal element, the oxygen diffusivity of the second oxide semiconductor layer 60 may be greater than that of indium oxide. The second metal element may include at least one selected from zinc (Zn), tin (Sn), germanium (Ge), and tungsten (W).

Among metal elements included in the second oxide semiconductor layer 60, the content of the second metal element may be greater than 1 at %, greater than or equal to 5 at %, or greater than or equal to 10 at %, and may be less than or equal to 20 at %, or less than 30 at %. When the content of the second metal element is excessively low, that is, 1 at % or less, the effect of the second metal element in increasing the diffusion of oxygen in the second oxide semiconductor layer 60 may be insignificant. When the content of the second metal element is excessively high, that is, 30 at % or more, the concentration of carriers in the second oxide semiconductor layer 60 may decrease, deteriorating electrical characteristics of the second oxide semiconductor layer 60.

The first oxide semiconductor layer 10 may be in contact with the first electrode 40 and the second electrode 50, and the second oxide semiconductor layer 60 may be in contact with the first oxide semiconductor layer 10 while being apart from portions of the first electrode 40 and the second electrode 50 with the first oxide semiconductor layer 10 therebetween. Because the second oxide semiconductor layer 60 is apart from portions of the first electrode 40 and the second electrode 50, carriers included in the second oxide semiconductor layer 60 may move rapidly in response to a voltage applied to a gate electrode 20, thereby improving the responsiveness of the semiconductor device 104. Because the first oxide semiconductor layer 10 is in contact with the first electrode 40 and the second electrode 50, material diffusion (for example, oxygen diffusion) from the second oxide semiconductor layer 60 to the first electrode 40 and the second electrode 50 may be reduced.

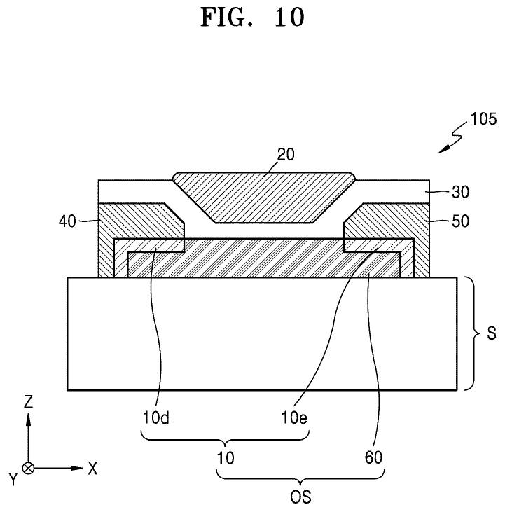

FIG. 10 is a view illustrating a semiconductor device 105 including a plurality of oxide semiconductor layers according to another embodiment. When comparing FIGS. 9 and 10, a first oxide semiconductor layer 10 included in the semiconductor device 105 shown in FIG. 10 may include a first sub-oxide semiconductor layer 10d, which is in contact with a first electrode 40, and a second sub-oxide semiconductor layer 10e, which is in contact with a second electrode 50. The first sub-oxide semiconductor layer 10d and the second sub-oxide semiconductor layer 10e may be apart from each other with a second oxide semiconductor layer 60 therebetween. The second oxide semiconductor layer 60 may be in contact with a gate insulating layer 30. That is, because the second oxide semiconductor layer 60 shown in FIG. 10 is positioned closer to a gate electrode 20 than the second oxide semiconductor layer 60 shown in FIG. 9 is to the gate electrode 20, the second oxide semiconductor layer 60 shown in FIG. 10 may respond more readily to a voltage applied to the gate electrode 20.

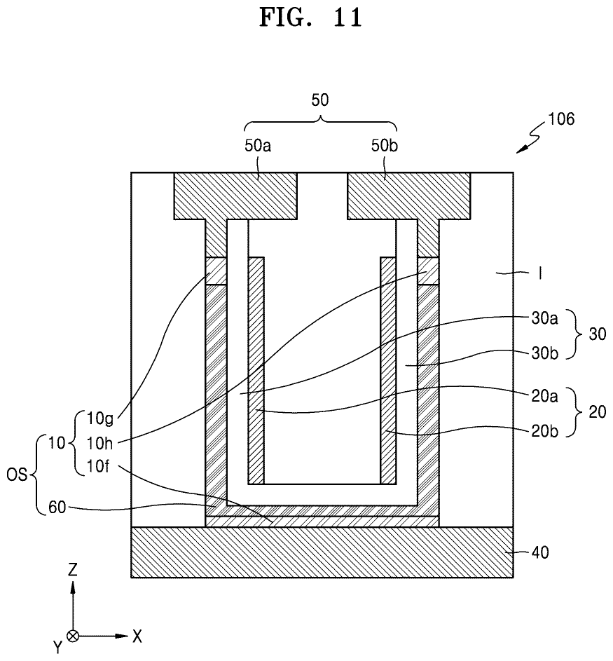

FIG. 11 is a view illustrating a semiconductor device 106 according to another embodiment. When comparing FIGS. 8 and 11, a first oxide semiconductor layer 10 may include a first sub-oxide semiconductor layer 10f in contact with a first electrode 40, a second sub-oxide semiconductor layer 10g in contact with a first sub-electrode 50a, and a third sub-oxide semiconductor layer 10h in contact with a second sub-electrode 50b. A second oxide semiconductor layer 60 may be disposed between the first sub-oxide semiconductor layer 10f and the second sub-oxide semiconductor layer 10g, and between the first sub-oxide semiconductor layer 10f and the third sub-oxide semiconductor layer 10h. The first sub-oxide semiconductor layer 10f, the second sub-oxide semiconductor layer 10g, and the third sub-oxide semiconductor layer 10h correspond to the first oxide semiconductor layer 10 described with reference to FIG. 9, and the second oxide semiconductor layer 60 corresponds to the second oxide semiconductor layer 60 described with reference to FIG. 9. Thus, repeated descriptions thereof are omitted.

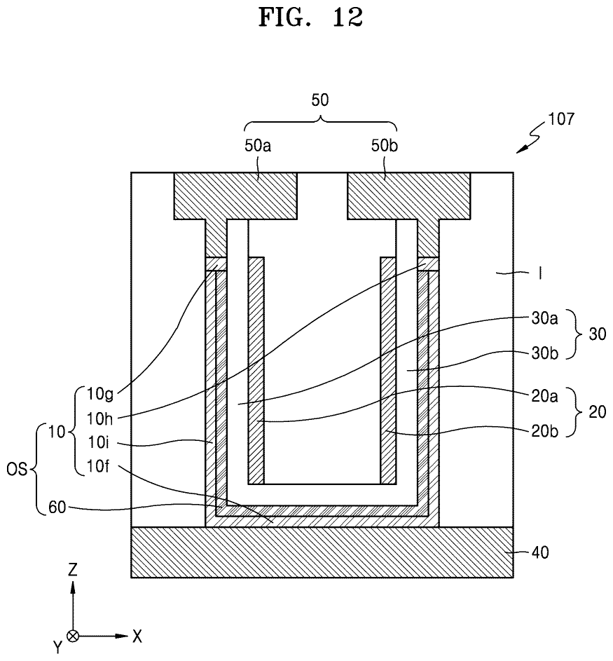

FIG. 12 is a view illustrating a semiconductor device 107 according to another embodiment. When comparing FIGS. 11 and 12, a first oxide semiconductor layer 10 may further include a fourth sub-oxide semiconductor layer 10i disposed on an outer surface of a second oxide semiconductor layer 60. The material of the fourth sub-oxide semiconductor layer 10i corresponds to that of the oxide semiconductor layer 10 described with reference to FIG. 1, and therefore, a description thereof is omitted. The fourth sub-oxide semiconductor layer 10i may limit and/or prevent a substance (for example, oxygen) contained in the first oxide semiconductor layer 10 from diffusing into an insulating layer I.

The semiconductor devices 100, 101, 102, 103, 104, 105, 106, and 107 described above may serve as transistors and may be components of memory devices. In an embodiment, when any of the gate insulating layers 30 described above includes a paraelectric material or a high-k material, the semiconductor device including the gate insulating layer 30 may operate as a memory device by further including a capacitor electrically connected to the first electrode 40 or the second electrode 50. However, embodiments are not limited thereto.

In an embodiment, when any of the gate insulating layers 30 described above includes a ferroelectric material, the semiconductor device including the gate insulating layer 30 may operate as a memory device without a capacitor. For example, the ferroelectric material may include a fluorite-based material, a perovskite, or the like. For example, the perovskite may include lead zirconate titanate (PZT), BaTiO₃, PbTiO₃, or the like. For example, the fluorite-based material may include an oxide containing at least one selected from hafnium (Hf), silicon (Si), aluminum (Al), zirconium (Zr), yttrium (Y), lanthanum (La), gadolinium (Gd), and strontium (Sr).

The gate insulating layers 30 of the semiconductor devices 100, 101, 102, 103, 104, 105, 106, and 107 of the embodiments may include only a paraelectric material or a ferroelectric material. Alternatively, the gate insulating layers 30 of the semiconductor devices 100, 101, 102, 103, 104, 105, 106, and 107 of the embodiments may have a multilayer structure including a paraelectric layer and a ferroelectric layer.

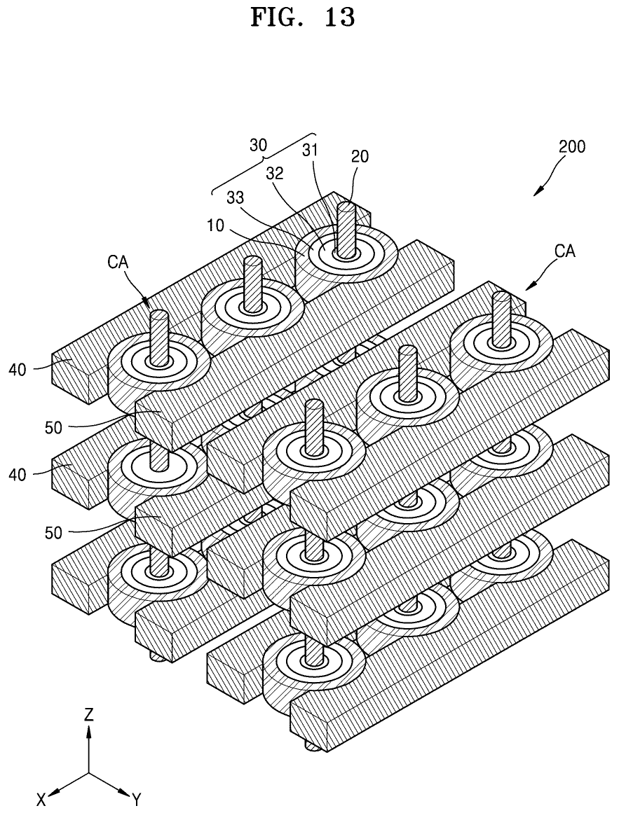

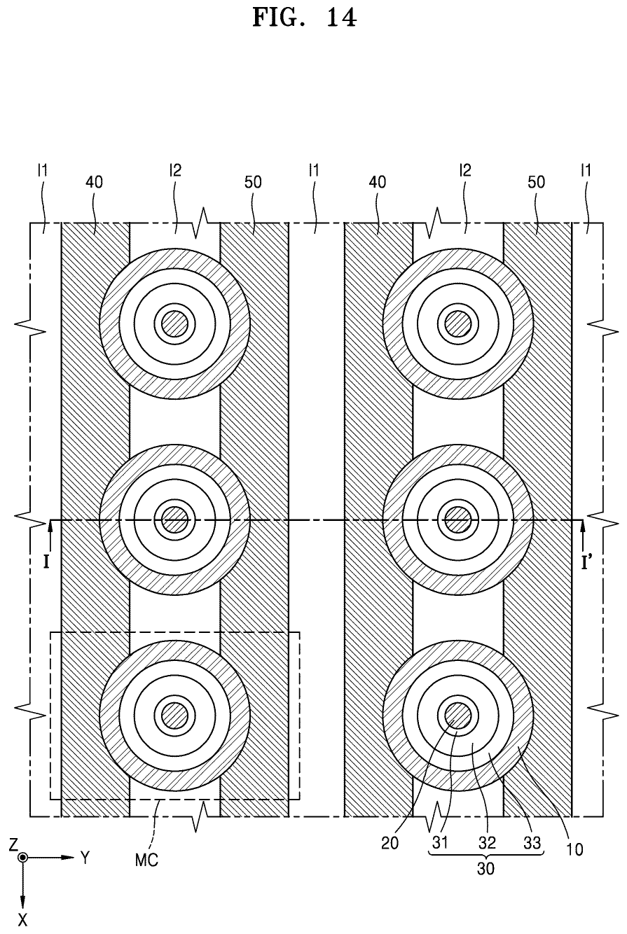

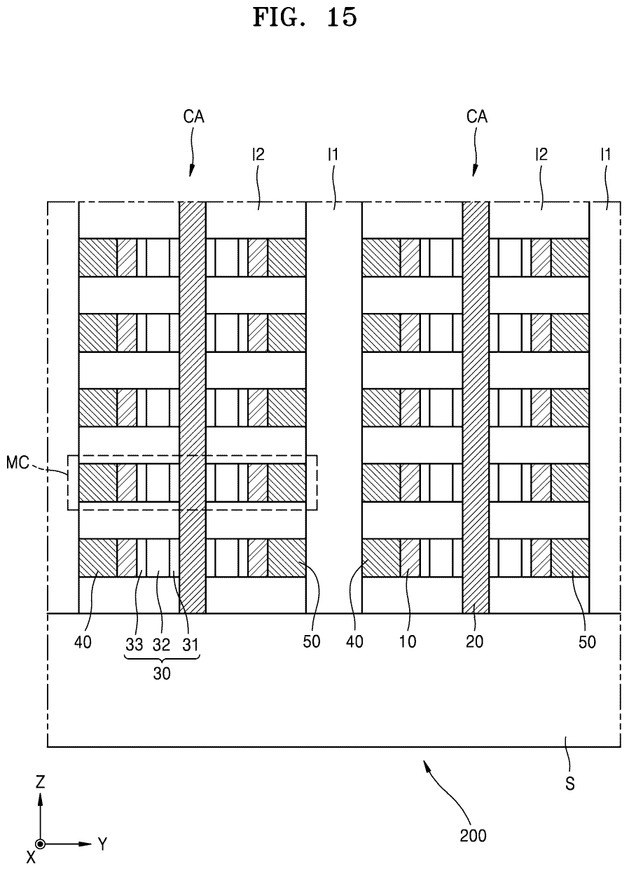

FIG. 13 is a perspective view schematically illustrating a structure of a memory device 200 that is a type of semiconductor device, according to an embodiment. FIG. 14 is a plan view illustrating the memory device 200 shown in FIG. 13; FIG. 15 is a cross-sectional view taken along line I-I′ of FIG. 14, schematically illustrating a cross-sectional structure of the memory device 200 according to an embodiment;

Referring to FIGS. 13 to 15, the memory device 200 may include a plurality of cell arrays CA that are two-dimensionally arranged on a substrate S. FIG. 13 illustrates an example in which the cell arrays CA are provided on the substrate S in a second direction (X-axis direction) and a third direction (Y-axis direction) that are parallel to the substrate S. Each of the cell arrays CA may extend in a first direction (Z-axis direction) perpendicular to the substrate S. Each of the cell arrays CA may include a plurality of memory cells MC arranged above the substrate S at a distance from each other in the first direction. Each of the memory cells MC may include a ferroelectric field-effect transistor (FeFET) having a metal-ferroelectric-metal-insulator-semiconductor (MFMIS) as described above.

First electrodes 40 and second electrodes 50 that extend in the second direction may be provided on opposite sides of a plurality of memory cells MC of a plurality of cell arrays CA arranged apart from each other in the second direction. Each of the first electrodes 40 and the second electrodes 50 may be shared by a plurality of memory cells MC of a plurality of cell arrays CA arranged in the second direction. The first electrodes 40 and the second electrodes 50 may be arranged apart from each other in the first direction and the third direction.

A first insulating material I1 may be provided between cell arrays CA arranged apart from each other in the third direction parallel to the substrate S. In addition, a second insulating material I2 may be provided between a plurality of memory cells MC arranged apart from each other in the first direction perpendicular to the substrate S. In addition, the second insulating material I2 may surround each of the memory cells MC and fill spaces between the first electrodes 40 and between the second electrodes 50.

The substrate S may include various materials. For example, the substrate S may include a monocrystal silicon substrate, a compound semiconductor substrate, or a silicon-on-insulator (SOI) substrate, but is not limited thereto. In addition, the substrate S may further include, for example, a dopant region formed by doping, electronic devices such as transistors, or a peripheral circuit for selecting and controlling a plurality of memory cells MC that store data.

The memory cells MC are stacked in the third direction (Z-axis direction) perpendicular to the substrate S, and each of the memory cells MC includes a gate electrode 20, a ferroelectric layer 31, an intermediate conductive layer 32, a paraelectric layer 33, an oxide semiconductor layer 10, a first electrode 40, and a second electrode 50. Here, the gate electrode 20 and the ferroelectric layer 31 may each extend in the third direction (Z-axis direction) perpendicular to the substrate S and may be shared by a plurality of memory cells MC. The ferroelectric layer 31, the intermediate conductive layer 32, and the paraelectric layer 33 may collectively be referred to as a gate insulating layer 30.

The gate electrode 20 may extend in the first direction perpendicular to the substrate S and may be shared by a plurality of memory cells MC forming one cell array CA. Each of the ferroelectric layer 31, the intermediate conductive layer 32, the paraelectric layer 33, and the oxide semiconductor layer 10 may have a cylindrical shell shape surrounding the gate electrode 20. For example, the ferroelectric layer 31 may surround a lateral surface of the gate electrode 20, the intermediate conductive layer 32 may surround a lateral surface of the ferroelectric layer 31, the paraelectric layer 33 may surround a lateral surface of the intermediate conductive layer 32, and the oxide semiconductor layer 10 may surround a lateral surface of the paraelectric layer 33. In other words, the gate insulating layer 30 (for example, the paraelectric layer 33, the intermediate conductive layer 32, and the ferroelectric layer 31) and the gate electrode 20 may be sequentially provided on an inner surface of the oxide semiconductor layer 10, while the first electrode 40 and the second electrode 50 may be provided on an outer surface of the oxide semiconductor layer 10. At least one selected from the first electrode 40 and the second electrode 50 may cover ⅕ or more of the outer surface of the oxide semiconductor layer 10. For example, each of the first electrode 40 and the second electrode 50 may cover ¼ of the outer surface of the oxide semiconductor layer 10.

The gate electrode 20, the ferroelectric layer 31, the intermediate conductive layer 32, the paraelectric layer 33, and the oxide semiconductor layer 10 of each of the memory cells MC may be apart from those of other memory cells MC in the first direction.

The materials of the gate electrode 20, the ferroelectric layer 31, the paraelectric layer 33, the oxide semiconductor layer 10, the first electrode 40, and the second electrode 50 are as described above, and thus, repeated descriptions are omitted. Although not shown in FIGS. 13 to 15, a second oxide semiconductor layer may be further disposed between the oxide semiconductor layer 10 and the paraelectric layer 33. The second oxide semiconductor layer may have a greater oxygen diffusivity than the oxide semiconductor layer 10, and the intermediate conductive layer 32 may function as a floating electrode. Like the gate electrode 20, the intermediate conductive layer 32 may include a conductive material. For example, the intermediate conductive layer 32 may include a metal, a metal nitride, a metal oxide, or polysilicon. For example, the intermediate conductive layer 32 may include at least one selected from W, TiN, TaN, WN, NbN, Mo, Ru, Ir, RuO, IrO, and highly-doped polysilicon. However, embodiments are not limited thereto. The intermediate conductive layer 32 may include the same material as the gate electrode 20, but is not limited thereto. For example, the intermediate conductive layer 32 may include a material different from a material included in the gate electrode 20.

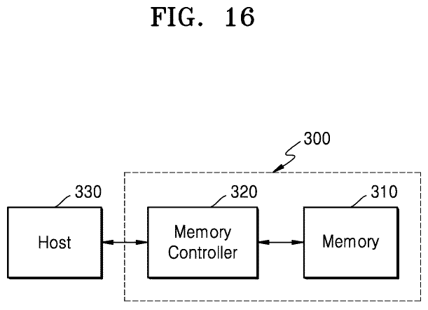

FIG. 16 is a block diagram illustrating an electronic system 300 according to an embodiment.

The electronic system 300 includes a memory 310 and a memory controller 320. The memory controller 320 may control the memory 310 for reading data from the memory 310 and/or writing data to the memory 310 in response to requests from a host 330. At least one selected from the memory 310 and the memory controller 320 may include any of the semiconductor devices of the embodiments described above.

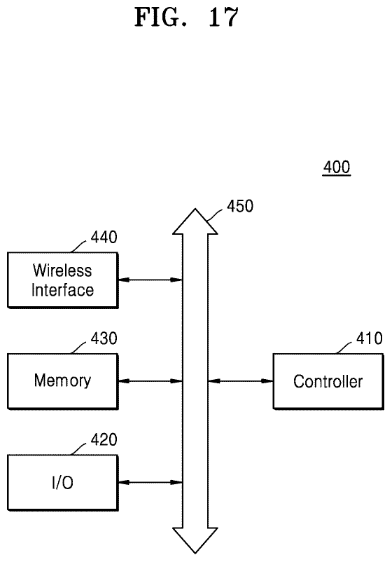

FIG. 17 is a block diagram illustrating an electronic system 400 according to an embodiment.

The electronic system 400 may form a wireless communication device or a device capable of transmitting and/or receiving information in a wireless environment. The electronic system 400 includes a controller 410, an input/output (I/O) device 420, a memory 430, and a wireless interface 440 that are connected to each other through a bus 450.

The controller 410 may include at least one selected from a microprocessor, a digital signal processor, and a similar processing device. The I/O device 420 may include at least one selected from a keypad, a keyboard, and a display. The memory 430 may be used to store instructions executed by the controller 410. For example, the memory 430 may be used to store user data. The electronic system 400 may use the wireless interface 440 to transmit/receive data through a wireless communication network. The wireless interface 440 may include an antenna and/or a wireless transceiver. The electronic system 400 may include any of the semiconductor devices of the embodiments described above.

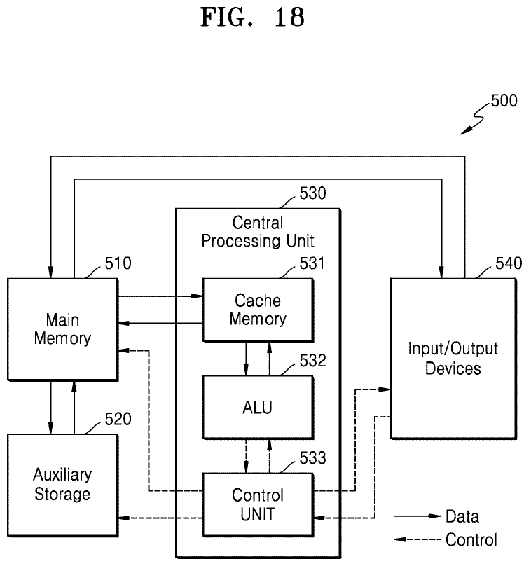

FIG. 18 is a conceptual view schematically illustrating a device architecture applicable to an electronic apparatus according to an embodiment. Referring to FIG. 18, an electronic apparatus 500 may include a main memory 510, an auxiliary storage 520, a central processing unit (CPU) 530, and input/output devices 540. The CPU 530 may include a cache memory 531, an arithmetic logic unit (ALU) 532, and a control unit 533. The cache memory 531 may be static random-access memory (SRAM) and may include any of the semiconductor devices of the embodiments described above. The main memory 510 may include a dynamic random-access memory (DRAM) device. Alternatively, the cache memory 531, the main memory 510, and the auxiliary storage 520 may each include any of the semiconductor devices of the embodiments described above. In some cases, the electronic apparatus 500 may be implemented in the form in which unit computing devices and unit memory devices are adjacent to each other on one chip without any distinction between sub-units.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
an amorphous oxide semiconductor layer comprising indium (In) and a first metal element, the first metal element being different from indium (In);
a gate electrode apart from the amorphous oxide semiconductor layer;
a gate insulating layer between the amorphous oxide semiconductor layer and the gate electrode; and
a first electrode and a second electrode apart from each other and in contact with the amorphous oxide semiconductor layer, wherein an oxygen diffusivity of the amorphous oxide semiconductor layer is less than an oxygen diffusivity of indium oxide (In₂O₃).

2. The semiconductor device of claim 1, wherein an amount of indium (In) is 70 at % or more of a total metal content in the amorphous oxide semiconductor layer.

3. The semiconductor device of claim 1, wherein an amount of the first metal element is more than 1 at % of a total metal content in the amorphous oxide semiconductor layer.

4. The semiconductor device of claim 1, wherein an amount of the first metal element is less than 30 at % of a total metal content in the amorphous oxide semiconductor layer.

5. The semiconductor device of claim 1, wherein an amount of the first metal element is 10 at % to 20 at % of a total metal content in the amorphous oxide semiconductor layer.

6. The semiconductor device of claim 1, wherein the first metal element comprises at least one selected from aluminum (Al), silicon (Si), gallium (Ga), yttrium (Y), and hafnium (Hf).

7. The semiconductor device of claim 1, wherein the amorphous oxide semiconductor layer has a thickness of 10 nm or less.

8. The semiconductor device of claim 1, wherein the amorphous oxide semiconductor layer comprises a crystalline phase in an amount greater than 0 % and less than or equal to 5 %.

9. The semiconductor device of claim 1, wherein
the amorphous oxide semiconductor layer is a first oxide semiconductor layer,
the semiconductor device further comprises a second oxide semiconductor layer, the second oxide semiconductor layer is in contact with the first oxide semiconductor layer, and the second oxide semiconductor layer is apart from the first electrode and the second electrode.

10. The semiconductor device of claim 9, wherein the second oxide semiconductor layer is in contact with the gate insulating layer.

11. The semiconductor device of claim 9, wherein an oxygen diffusivity of the second oxide semiconductor layer is greater than an oxygen diffusivity of the first oxide semiconductor layer.

12. The semiconductor device of claim 9, wherein
the second oxide semiconductor layer comprises indium (In) in an amount of 70 at % or more based on a total metal content thereof, and
the second oxide semiconductor layer further comprises a second metal element, the second metal element being different from indium (In) and the first metal element.

13. The semiconductor device of claim 12, wherein the second metal element comprises at least one selected from zinc (Zn), tin (Sn), germanium (Ge), and tungsten (W).

14. The semiconductor device of claim 1, wherein
a bottom portion of the amorphous oxide semiconductor layer comprises is in contact with the first electrode,
a first vertical extension portion of the amorphous oxide semiconductor layer extends from an end of the bottom portion in a direction perpendicular to the first electrode, and
a second vertical extension portion extending from an other end of the bottom portion in the direction perpendicular to the first electrode.

15. The semiconductor device of claim 1, wherein
the amorphous oxide semiconductor layer has a cylindrical shell shape,
the gate insulating layer is on an inner surface of the amorphous oxide semiconductor layer,
the gate electrode is on an inner surface of the gate insulating layer, and
the first electrode and the second electrode are on an outer surface of the amorphous oxide semiconductor layer.

16. The semiconductor device of claim 15, wherein
at least one of the first electrode and the second electrode surrounds ⅕ or more of the outer surface of the amorphous oxide semiconductor layer.

17. The semiconductor device of claim 1, wherein the gate insulating layer comprises a ferroelectric material.

18. An electronic apparatus comprising:
a memory device; and
a memory controller configured to control the memory device to at least one of read data from the memory device or write data to the memory device, wherein the memory device includes a semiconductor device,
the semiconductor device comprises an amorphous oxide semiconductor layer, a gate electrode apart from the amorphous oxide semiconductor layer, a gate insulating layer between the amorphous oxide semiconductor layer and the gate electrode, a first electrode, and a second electrode,
the amorphous oxide semiconductor layer includes indium (In) and a first metal element,
the first metal element is different from indium (In),
the first electrode and the second electrode are apart from each other and in contact with the amorphous oxide semiconductor layer,
an oxygen diffusivity of the amorphous oxide semiconductor layer is less than an oxygen diffusivity of indium oxide (In₂O₃).

19. A method of manufacturing a semiconductor device, the method comprising:
forming an amorphous oxide semiconductor layer on a substrate at a process temperature of 300 °C or less;
forming a gate insulating layer on the amorphous oxide semiconductor layer; and
forming a gate electrode on the gate insulating layer, wherein the amorphous oxide semiconductor layer comprises indium (In) and a first metal element,
the first metal element is different from indium (In), and
an oxygen diffusivity of the amorphous oxide semiconductor layer is less than an oxygen diffusivity of indium oxide (In₂O₃).

20. The method of claim 19, wherein the first metal element comprises at least one selected from aluminum (Al), silicon (Si), gallium (Ga), yttrium (Y), or hafnium (Hf).
